(19) United States
(12) Patent Application Publication
(10) Pub. No.: US 2014/0131698 A1
(43) Pub. Date: May 15, 2014

(54) CHANNEL LAYER AND THIN FILM TRANSISTOR INCLUDING THE SAME

(71) Applicant: Samsung Electronics Co., Ltd., Suwon-Si (KR)

(72) Inventors: Eok-su KIM, Seongnam-si (KR); Sun-Hee LEE, Seoul (KR)

(21) Appl. No.: 13/922,814

(22) Filed: Jun. 20, 2013

(30) Foreign Application Priority Data
Nov. 15, 2012 (KR) 10-2012-0129784

(51) Int. Cl. H01L 29/24; H01L 29/786

(52) U.S. Cl. CPC H01L 29/24; H01L 29/786
USPC 257/42; 257/613; 257/347

(57) ABSTRACT

A channel layer may include a plurality of transition metal dichalcogenide (TMD) material layers and an insulator layer between a pair of the plurality of TMD material layers.

### CROSS-REFERENCE TO RELATED APPLICATION

This application claims the benefit of Korean Patent Application No. 10-2012-0129784, filed on Nov. 15, 2012, in the Korean Intellectual Property Office, the disclosure of which is incorporated herein in its entirety by reference.

### BACKGROUND

1. Field

Example embodiments relate to channel layers and thin film transistors including the same, more particularly, to thin film transistors capable of achieving increased carrier mobility.

2. Description of the Related Art

Thin film transistors are broadly used in various electronic devices for various purposes. For example, thin film transistors may be used as switching devices, driving devices, and basic elements of various circuits. In particular, because thin film transistors may be formed on a glass substrate or a plastic substrate, they may be appropriately used in flat panel display apparatuses (e.g., liquid crystal display apparatuses or organic light emitting display apparatuses).

Characteristics of a thin film transistor may vary according to a material of a channel layer. The material of the channel layer may be an essential or important factor for determining the characteristics of the thin film transistor. Currently, research for increasing carrier mobility is being actively conducted to improve operation characteristics of thin film transistors.

### SUMMARY

Example embodiments provide channel layers and thin film transistors including the same capable of achieving a relatively high carrier mobility due to an improved channel layer.

Additional aspects will be set forth in part in the description which follows and, in part, will be apparent from the description, or may be learned by practice of example embodiments.

According to example embodiments, a channel layer may include a plurality of transition metal dichalcogenide (TMD) material layers and an insulator layer between a pair of the plurality of TMD material layers.

Each of the plurality of TMD material layers may be formed in one of a monolayered and a multilayered structure. One TMD material layer of the plurality of TMD material layers and the insulator layer may be alternately stacked. At least two pairs of the plurality of TMD material layers and the insulator layer therebetween may be repeatedly stacked.

A TMD material of each of the plurality of TMD material layers may be a compound formed of an atom of a transition metal and two atoms of a chalcogen, the chalcogen including one of sulfur (S), selenium (Se), and tellurium (Te). Each of the plurality of TMD material layers may include one of molybdenum disulfide (MoS₂), molybdenum diselenide (MoSe₂), tungsten disulfide (WS₂), tungsten diselenide (WSe₂), and molybdenum ditelluride (MoTe₂). The insulator layer may include a high-K insulator material.

According to example embodiments, a thin film transistor may include the channel layer, a gate configured to control electrical characteristics of the channel layer, and a source and a drain contacting the channel layer.

The gate may be one of between the channel layer and a substrate and on the channel layer. A gate insulating layer may be between the gate and the channel layer. A passivation layer may be on the channel layer. The gate may include a first gate between a substrate and the channel layer, and a second gate on the channel layer. A gate insulating layer may be between the first gate and the channel layer. The passivation layer may be between the channel layer and the second gate.

The channel layer may include one TMD material layer of the plurality of TMD material layers and the insulator layer alternately stacked. A TMD material of each of the plurality of TMD material layers may be a compound formed of an atom of a transition metal and two atoms of a chalcogen, the chalcogen including one of sulfur (S), selenium (Se), and tellurium (Te). Each of the plurality of TMD material layers may include one of molybdenum disulfide (MoS₂), molybdenum diselenide (MoSe₂), tungsten disulfide (WS₂), tungsten diselenide (WSe₂), and molybdenum ditelluride (MoTe₂). The insulator layer may include a high-K insulator material.

As described above, according to example embodiments, because a channel layer is formed to include a plurality of transition metal dichalcogenide (TMD) material layers and insulator layers disposed between the TMD material layers, a thin film transistor having increased carrier mobility may be achieved.

### BRIEF DESCRIPTION OF THE DRAWINGS

These and/or other aspects will become apparent and more readily appreciated from the following description of the embodiments, taken in conjunction with the accompanying drawings of which:

FIG. 1 is a cross-sectional view of a thin film transistor according to example embodiments;

FIG. 2 is a schematic view showing an example of the structure of a channel layer illustrated in FIG. 1;

FIG. 3 is a schematic view showing the structure of a transition metal dichalcogenide (TMD) material layer formed of a monolayered TMD material;

FIG. 4 is a schematic view showing the structure of the TMD material layer formed of a multilayered TMD material; and

FIG. 5 is a cross-sectional view of a thin film transistor according to example embodiments.

### DETAILED DESCRIPTION

Reference will now be made in detail to embodiments, examples of which are illustrated in the accompanying drawings, wherein like reference numerals refer to like elements throughout. In this regard, example embodiments may have different forms and should not be construed as being limited to the descriptions set forth herein. Accordingly, the example embodiments are merely described below, by referring to the figures, to explain aspects of the present description.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

Parts having no relationship with the description are omitted for clarity, and the same or similar constituent elements are indicated by the same reference numeral throughout the specification.

It will be understood that, although the terms “first”, “second”, etc. may be used herein to describe various elements, components, regions, layers and/or sections, these elements, components, regions, layers and/or sections are not to be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments are not to be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, is to be interpreted as having a meaning that is consistent with their meaning in the context of the relevant art and will not be interpreted in an idealized or overly formal sense unless expressly so defined herein.

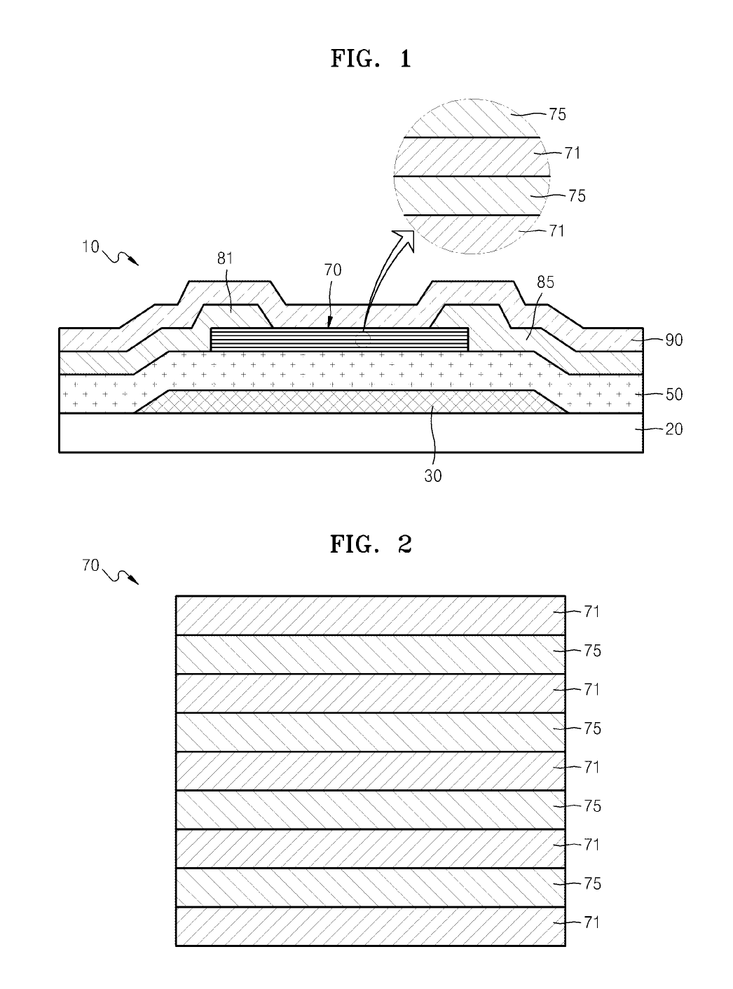

FIG. 1 is a cross-sectional view of a thin film transistor 10 according to example embodiments. Although the thin film transistor 10 in FIG. 1 is of a bottom gate type, a bottom gate type serves only as an example, and the thin film transistor 10 may also be a top gate type.

Referring to FIG. 1, the thin film transistor 10 includes a gate 30 formed on a substrate 20, a channel layer 70 formed on the gate 30, and a source 81 and a drain 85 contacting the channel layer 70. A gate insulating layer 50 may be further formed between the gate 30 and the channel layer 70. Also, a passivation layer 90 may be further formed to cover the channel layer 70, the source 81, and the drain 85. Alternatively, the thin film transistor 10 may include the gate 30 formed on the passivation layer 90 and, in example embodiments, the thin film transistor 10 is a top gate type.

The substrate 20 may be a general substrate used to manufacture a semiconductor device. For example, the substrate 20 may be a glass substrate, a plastic substrate, or a silicon substrate. An oxide layer (not shown), e.g., an SiO₂ layer formed by thermally oxidizing a silicon substrate, may be formed on a surface of the substrate 20.

The gate 30 may be used to control electrical characteristics of the channel layer 70 and may be formed of a conductive material, e.g., metal or conductive oxide that is a general electrode material. For example, the gate 30 may be formed of metal (e.g., titanium (Ti), platinum (Pt), ruthenium (Ru), gold (Au), silver (Ag), molybdenum (Mo), aluminum (Al), tungsten (W), or copper (Cu)), conductive oxide (e.g., indium zinc oxide (IZO (or InZnO)) or aluminum zinc oxide (AZO (or AIZnO))).

The gate insulating layer 50 may be formed of a general insulating material used in a semiconductor device. For example, the gate insulating layer 50 may be formed of HfO₂, Al₂O₃, or Si₃N₄, all of which are high-K materials having a permittivity higher than that of SiO₂ or SiO₂. The gate insulating layer 50 may be formed in a monolayered or multilayered structure.

The channel layer 70 includes at least two transition metal dichalcogenide (TMD) material layers 71 and an insulator layer 75 disposed therebetween. That is, the channel layer 70 may include at least two TMD material layers 71 and at least one insulator layer 75.

The channel layer 70 may be formed by alternately stacking the TMD material layers 71 and the insulator layers 75. For example, in the channel layer 70, as illustrated in FIG. 2, at least two pairs of the TMD material layer 71 and the insulator layer 75 may be repeatedly stacked. FIG. 2 shows an example of the structure of the channel layer 70, in which four pairs of the TMD material layer 71 and the insulator layer 75 are repeatedly stacked and another TMD material layer 71 is further formed as an uppermost layer. Although FIG. 2 shows an example in which pairs of the TMD material layer 71 and the insulator layer 75 are repeatedly stacked, example embodiments are not limited thereto, and the number of stacked pairs may be varied as long as the channel layer 70 includes at least two TMD material layers 71 and at least one insulator layer 75.

In the above-described channel layer 70, each TMD material layer 71 may be formed in a monolayered or multilayered structure. Because a TMD material is formed in a layered structure, each of the TMD material layers 71 spaced apart from each other by the insulator layer 75 in the channel layer 70 may be formed in a monolayered or multilayered structure by using the TMD material.

Also, in the channel layer 70, the insulator layer 75 may be formed to include a high-K insulator material. For example, the insulator layer 75 may be formed of a high-K material (e.g., HfO₂, Al₂O₃, or Si₃N₄).

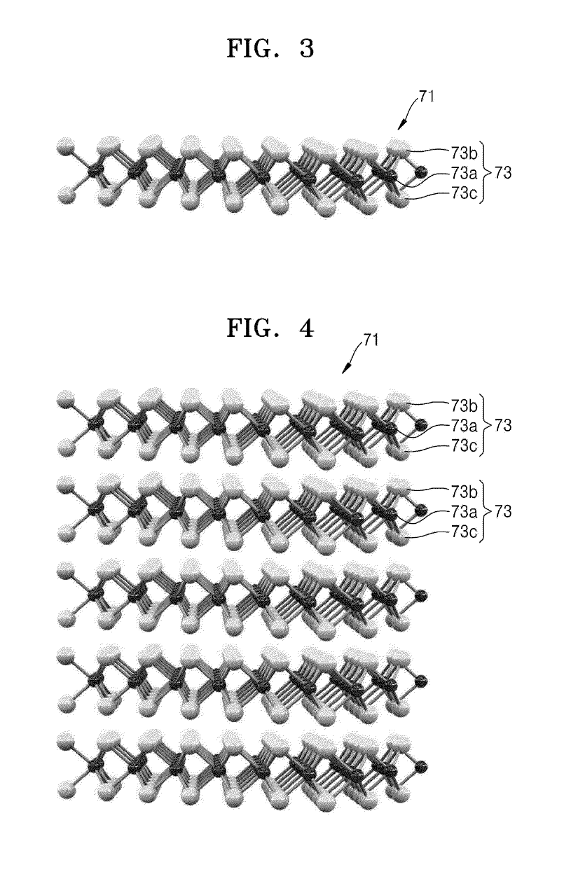

FIG. 3 is a schematic view showing the structure of the TMD material layer 71 formed of a monolayered TMD material 73. FIG. 4 is a schematic view showing the structure of the TMD material layer 71 formed of a multilayered TMD material 73.

Referring to FIGS. 3 and 4, the TMD material 73 is a compound formed of an atom 73a of a transition metal and two chalcogens 73b and 73c, formed in a layered structure, wherein the layered structure is for forming a strong in-plane covalent bond between atoms and for forming a weak interlayer connection with the van der Waals force. The above-described TMD material 73 has characteristics of a semiconductor having a band gap.

Because the TMD material layer 71 is formed of the above-described TMD material 73, the TMD material layer 71 may have a layered structure. Therefore, each TMD material layer 71 may be formed in a monolayered structure as illustrated in FIG. 3 or in a multilayered structure as illustrated in FIG. 4.

As described above, the TMD material 73 of the TMD material layer 71 may be a compound formed of the transition metal 73a and the two chalcogens 73b and 73c. In example embodiments, the chalcogen material 73b and 73c may include sulfur (S), selenium (Se), or tellurium (Te). For example, the TMD material layer 71 may include MoS₂, MoSe₂, WS₂, WSe₂, or MoTe₂.

In the monolayered TMD material layer, when a high-K insulator (e.g., the gate insulating layer 50 and/or the passivation layer 90) is used to form layers adjacent to the TMD material layer, scattering of moving carriers may be reduced, and thus a high mobility may be achieved. Also, when the TMD material layer is formed of the multilayered TMD material, the number of valid semiconductor layers to which carriers may be moved is thus increased, and a relatively high mobility may be achieved.

In the thin film transistor 10, because the channel layer 70 is formed by alternately stacking the monolayered or multilayered TMD material layers 71 and the insulator layers 75, both an effect of reducing scattering in a monolayered TMD material layer and an effect of increasing moving paths in a multilayer TMD material layer may be achieved, and thus a carrier mobility of the channel layer 70 may be further increased.

Referring back to FIG. 1, the source 81 and the drain 85 may be formed of a conductive material to contact two ends of the channel layer 70. For example, the source 81 and the drain 85 may be formed of metal (e.g., Pt, Ru, Au, Ag, Mo, Al, W or Cu), or of conductive oxide (e.g., IZO (or InZnO) or AZO (or AIZnO)). The source 81 and the drain 85 may be formed as a monolayer or a multilayer.

Although the thin film transistor 10 includes one gate 30 at a bottom or top side in the above description regarding FIG. 1, example embodiments are not limited thereto, and two gates may be formed at both the bottom and top sides.

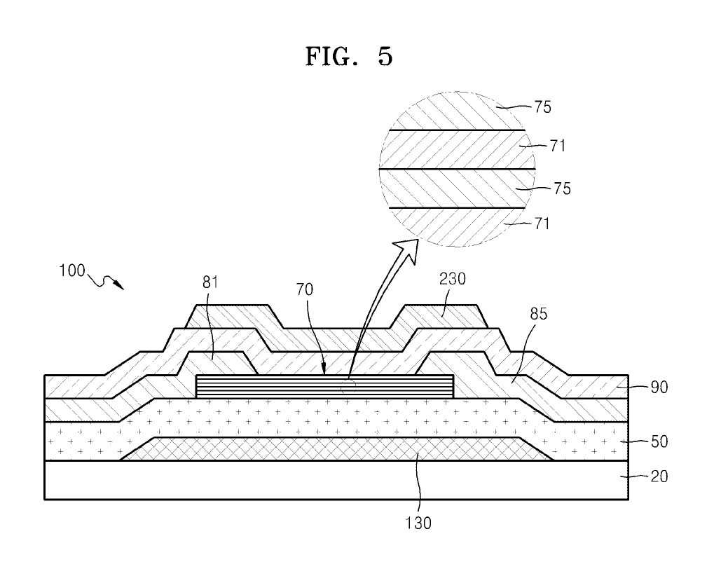

FIG. 5 is a cross-sectional view of a thin film transistor 100 according to example embodiments, which is formed in a double gate structure having both a top gate and a bottom gate.

Referring to FIG. 5, the thin film transistor 100 includes a first gate 130 formed on the substrate 20, the channel layer 70 formed on the first gate 130, the source 81 and the drain 85 contacting the channel layer 70, and a second gate 230 disposed on the channel layer 70. The gate insulating layer 50 may be further formed between the first gate 130 and the channel layer 70. Also, the passivation layer 90 may be further formed to cover the channel layer 70, the source 81, and the drain 85. The second gate 230 may be formed on the passivation layer 90 to correspond to the channel layer 70. Except for the first and second gates 130 and 230, the other elements of the thin film transistor 100 illustrated in FIG. 5 may be substantially the same as those of the thin film transistor 10 illustrated in FIG. 1. Therefore, like elements in FIGS. 1 and 5 are denoted by like reference numerals and repeated descriptions thereof are not provided here.

Like the gate 30 illustrated in FIG. 1, the first and second gates 130 and 230 are used to control electrical characteristics of the channel layer 70 and may be formed of a conductive material, e.g., metal or conductive oxide that is a general electrode material. For example, the first and second gates 130 and 230 may be formed of metal (e.g., Ti, Pt, Ru, Au, Ag, Mo, Al, W or Cu), or of conductive oxides, e.g., IZO (or InZnO) or AZO (or AIZnO).

It should be understood that example embodiments described therein should be considered in a descriptive sense only and not for purposes of limitation. Descriptions of features or aspects within each embodiment should typically be considered as available for other similar features or aspects in other embodiments.

What is claimed is:

1. A channel layer comprising a plurality of transition metal dichalcogenide (TMD) material layers and an insulator layer between a pair of the plurality of TMD material layers.

2. The channel layer of claim 1, wherein each of the plurality of TMD material layers is formed in one of a monolayered and a multilayered structure.

3. The channel layer of claim 1, wherein one TMD material layer of the plurality of TMD material layers and the insulator layer alternately stacked.

4. The channel layer of claim 3, wherein at least two pairs of the plurality of TMD material layers and the insulator layer therebetween are repeatedly stacked.

5. The channel layer of claim 4, wherein each of the plurality of TMD material layers is formed in one of a monolayered and a multilayered structure.

6. The channel layer of claim 1, wherein a TMD material of each of the plurality of TMD material layers is a compound formed of an atom of a transition metal and two atoms of a chalcogen, the chalcogen including one of sulfur (S), selenium (Se), and tellurium (Te).

7. The channel layer of claim 6, wherein each of the plurality of TMD material layers includes one of molybdenum disulfide (MoS₂), molybdenum diselenide (MoSe₂), tungsten disulfide (WS₂), tungsten diselenide (WSe₂), and molybdenum ditelluride (MoTe₂).

8. The channel layer of claim 1, wherein the insulator layer includes a high-K insulator material.

9. A thin film transistor comprising:
the channel layer of claim 1;
a gate configured to control electrical characteristics of the channel layer; and
a source and a drain contacting the channel layer.

10. The thin film transistor of claim 9, wherein the gate is one of between the channel layer and a substrate and on the channel layer.

11. The thin film transistor of claim 10, further comprising:
a gate insulating layer between the gate and the channel layer.

12. The thin film transistor of claim 11, further comprising:
a passivation layer on the channel layer.

13. The thin film transistor of claim 9, wherein the gate comprises:
a first gate between a substrate and the channel layer; and
a second gate on the channel layer.

14. The thin film transistor of claim 13, further comprising:
a gate insulating layer between the first gate and the channel layer.

15. The thin film transistor of claim 14, further comprising:
a passivation layer on the channel layer.

16. The thin film transistor of claim 15, wherein the passivation layer is between the channel layer and the second gate.

17. The thin film transistor of claim 9, wherein the channel layer includes one TMD material layer of the plurality of TMD material layers and the insulator layer alternately stacked.

18. The thin film transistor of claim 9, wherein a TMD material of each of the plurality of TMD material layers is a compound formed of an atom of a transition metal and two atoms of a chalcogen, the chalcogen including one of sulfur (S), selenium (Se), and tellurium (Te).

19. The thin film transistor of claim 18, wherein each of the plurality of TMD material layers includes one of molybdenum disulfide (MoS₂), molybdenum diselenide (MoSe₂), tungsten disulfide (WS₂), tungsten diselenide (WSe₂), and molybdenum ditelluride (MoTe₂).

20. The thin film transistor of claim 9, wherein the insulator layer includes a high-K insulator material.
